(19) United States
(12) Patent Application Publication
(10) Pub. No.: US 2026/0304660 A1
(43) Pub. Date: Oct. 1, 2026

(54) METHOD OF MANUFACTURING DISPLAY DEVICE AND METHOD OF MANUFACTURING ELECTRONIC DEVICE INCLUDING THE SAME

(71) Applicant: Samsung Display Co., Ltd., Yongin-si (KR)

(72) Inventor: JONGMIN LEE, Yongin-si (KR)

(21) Appl. No.: 19/455,617

(22) Filed: Jan. 21, 2026

(30) Foreign Application Priority Data
Mar. 27, 2025 (KR) 10-2025-0039527

(51) Int. Cl. H05K 5/03; G06F 1/16; H05K 5/10

(52) U.S. Cl. CPC H05K 5/03; G06F 1/1637; H05K 5/10

(57) ABSTRACT

In a method of manufacturing a display device, the method includes: providing a preliminary laminated body including a glass substrate and a mother substrate on an upper surface of the glass substrate and in which cell areas are defined; forming first patterns on an upper surface of the mother substrate, overlapping the cell areas, and spaced apart from each other; forming a cover layer in contact with the upper surface of the mother substrate exposed by the first patterns; forming a second pattern on the cover layer; arranging a protective film having acid resistance on the first pattern and the second pattern; etching a rear surface of the glass substrate; and removing the protective film.

### CROSS-REFERENCE TO RELATED APPLICATION

The present application claims priority to and the benefit of Korean Patent Application No. 10-2025-0039527, filed on Mar. 27, 2025, in the Korean Intellectual Property Office, the entire disclosure of which is incorporated herein by reference.

### BACKGROUND

Aspects of some embodiments of the present disclosure described herein relate to a method of manufacturing a display device.

Multimedia devices such as televisions, mobile phones, tablets, navigation systems, and game consoles include a display device that displays images to users through a display screen. The display device may include a display panel that generates images and an input sensor that senses a touch of the user. A process of manufacturing a display device may include cutting the display device from a mother substrate.

The above information disclosed in this Background section is only for enhancement of understanding of the background and therefore the information discussed in this Background section does not necessarily constitute prior art.

### SUMMARY

Aspects of some embodiments of the present disclosure described herein relate to a method of manufacturing a display device, and for example, to a method of manufacturing a display device having relatively improved process reliability.

Aspects of some embodiments of the present disclosure include a method of manufacturing a display device having relatively improved process reliability. Aspects of some embodiments of the present disclosure may also include a method of manufacturing a display device, the method including a process of etching a glass substrate and removing a protective film, the method having relatively improved process reliability.

According to some embodiments, a method of manufacturing a display device includes providing a preliminary laminated body including a glass substrate and a mother substrate on an upper surface of the glass substrate and in which cell areas are defined, forming first patterns arranged on an upper surface of the mother substrate, overlapping the cell areas, and spaced apart from each other, forming a cover layer in contact with the upper surface of the mother substrate exposed by the first patterns, forming a second pattern on the cover layer, arranging a protective film having acid resistance on the first pattern and the second pattern, etching a rear surface of the glass substrate, and removing the protective film.

According to some embodiments, the cover layer may be in contact with side surfaces of the first patterns and upper surfaces of the first patterns.

According to some embodiments, an end of the cover layer may be exposed from the second pattern and may be in contact with the protective film.

According to some embodiments, in a plan view, an area in which the cover layer overlaps upper surfaces of the first patterns may be larger than an area in which the second pattern overlaps the upper surfaces of the first patterns.

According to some embodiments, the forming of the first patterns may include discharging a first liquid solution onto the upper surface of the mother substrate in an inkjet method, and the first liquid solution may contain an acryl-based resin.

According to some embodiments, the forming of the second pattern may include discharging a second liquid solution onto the upper surface of the mother substrate in an inkjet method.

According to some embodiments, the cover layer may have acid resistance.

According to some embodiments, the cover layer may contain an acryl-based inorganic material.

According to some embodiments, a thickness of the cover layer may be in a range of 1 micrometer (μm) to 10 μm.

According to some embodiments, the second pattern may include a central portion having a first thickness and a side portion having a second thickness smaller than the first thickness.

According to some embodiments, the method may further include, after the forming of the first patterns, forming a sketch line by etching the mother substrate exposed by the first patterns in a direction from the upper surface of the mother substrate to the glass substrate.

According to some embodiments, the etching of the rear surface of the glass substrate may include dipping the preliminary laminated body into an etching solution.

According to some embodiments, in the removing of the protective film, the second pattern and the cover layer attached to a rear surface of the protective film may be removed together with the protective film.

According to some embodiments, the method may further include, after the forming of the cover layer, forming recessed patterns by etching an upper surface of the cover layer, wherein the second pattern may be filled in at least some of the recessed patterns, and on a cross section, each of the recessed patterns may have a first portion of which a width is increased in a direction closer to the glass substrate and a second portion of which a width is decreased in the direction closer to the glass substrate.

According to some embodiments, the upper surface of the cover layer, which defines each of the recessed patterns, may include a curved surface.

According to some embodiments, on a cross section, each of the recessed patterns may have an inverted tapered shape.

According to some embodiments, a sub-laminated body may be formed from the preliminary laminated body by the removing of the protective film, the method may further comprise arranging the sub-laminated body on a stage, and in the arranging of the sub-laminated body on the stage, the first patterns may be in contact with the stage.

According to some embodiments, the forming of the cover layer may include forming a first sub-cover layer and forming a second sub-cover layer on the first sub-cover layer, and an adhesive force between the second sub-cover layer and the first sub-cover layer may be greater than an adhesive force between the first sub-cover layer and the first pattern.

According to some embodiments, a method of manufacturing an electronic device configured to provide an image and including a display device and a power module includes providing a preliminary laminated body including a glass substrate and a mother substrate on an upper surface of the glass substrate and in which cell areas are defined, forming first patterns overlapping the cell areas on an upper surface of the mother substrate and spaced apart from each other, forming a cover layer in contact with the upper surface of the mother substrate exposed by the first patterns, forming a second pattern on the cover layer, arranging a protective film on the first pattern and the second pattern, etching a rear surface of the glass substrate, and removing the protective film.

According to some embodiments, an electronic device including a display device and a power module and configured to provide an image is manufactured by a method of manufacturing a display device, the method including providing a preliminary laminated body including a glass substrate and a mother substrate on an upper surface of the glass substrate and in which cell areas are defined, forming first patterns overlapping the cell areas on an upper surface of the mother substrate and spaced apart from each other, forming a cover layer in contact with the upper surface of the mother substrate exposed by the first patterns, forming a second pattern on the cover layer, arranging a protective film on the first pattern and the second pattern, etching a rear surface of the glass substrate, and removing the protective film.

### BRIEF DESCRIPTION OF THE DRAWINGS

The above and other aspects and features of embodiments according to the present disclosure will become more apparent by describing in more detail aspects of some embodiments thereof with reference to the accompanying drawings.

FIG. 1 is a block diagram of an electronic device according to some embodiments of the present disclosure.

FIG. 2 is a schematic view of the electronic device according to some embodiments.

FIG. 3 is a perspective view of the electronic device according to some embodiments of the present disclosure.

FIG. 4 is an exploded perspective view of the electronic device according to some embodiments of the present disclosure.

FIG. 5 is a flowchart of a method of manufacturing a display device according to some embodiments of the present disclosure.

FIGS. 6 to 15 are views illustrating operations of the method of manufacturing a display device according to some embodiments of the present disclosure.

FIGS. 16 and 17 are views illustrating operations of the method of manufacturing a display device according to some embodiments of the present disclosure.

FIGS. 18 and 19 are views illustrating operations of the method of manufacturing a display device according to some embodiments of the present disclosure.

FIG. 20 is a view illustrating operations of the method of manufacturing a display device according to some embodiments of the present disclosure.

### DETAILED DESCRIPTION

Because embodiments according to the present disclosure may be variously modified and may have various forms, aspects of some embodiments thereof will be illustrated in the drawings and will be described herein in more detail. However, it should be understood that embodiments according to the present disclosure are not limited to a specific disclosure and includes all changes, equivalents, and substitutes included in the spirit and scope of the present disclosure.

In the specification, the expression that a first component (or area, layer, part, portion, etc.) is “located on”, “connected with” or “coupled to” a second component means that the first component is directly located on/connected with/coupled to the second component or means that a third component is interposed therebetween.

The same reference numerals refer to the same components. Further, in the drawings, the thickness, the ratio, and the dimension of components are exaggerated for effective description of technical contents. The expression “and/or” includes one or more combinations which associated components are capable of defining.

Although the terms “first,” “second,” etc., may be used to describe various components, the components should not be limited by the terms. The terms are only used to distinguish one component from another component. For example, without departing from the right scope of the present disclosure, a first component may be referred to as a second component, and similarly, the second component may be also referred to as the first component. Singular expressions include plural expressions unless clearly otherwise indicated in the context.

Also, the terms “under”, “below”, “on”, “above”, etc. are used to describe the correlation of components illustrated in drawings. The terms that are relative in concept are described based on a direction illustrated in drawings.

It will be understood that the terms “include”, “comprise”, “have”, etc. specify the presence of features, numbers, steps, operations, elements, or components, described in the specification, or a combination thereof, and do not exclude in advance the presence or additional possibility of one or more other features, numbers, steps, operations, elements, or components or a combination thereof.

Unless otherwise defined, all terms (including technical terms and scientific terms) used in the present specification have the same meaning as commonly understood by those skilled in the art to which the present disclosure belongs. Further, terms defined in commonly used dictionaries should be interpreted as having meanings in the context of the relevant technology and should not be interpreted as excessively ideal or formal meanings unless explicitly defined here.

Hereinafter, aspects of some embodiments of the present disclosure will be described in more detail with reference to the accompanying drawings.

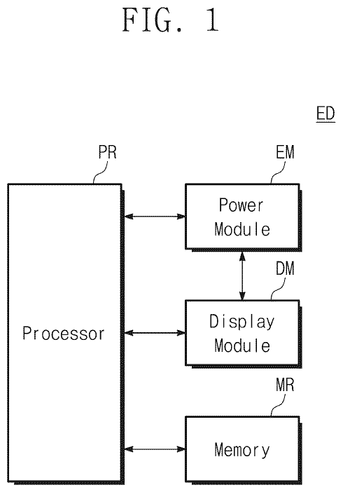

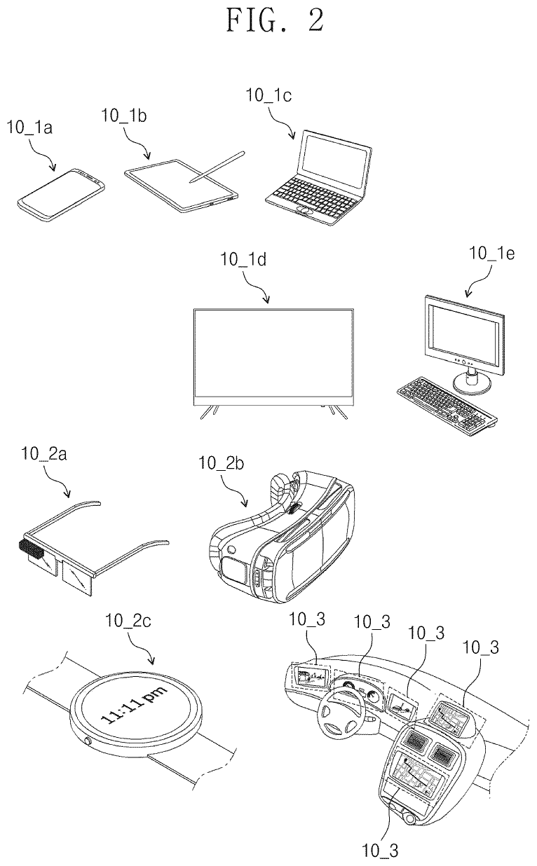

FIG. 1 is a block diagram of an electronic device according to some embodiments of the present disclosure. FIG. 2 is a schematic view of the electronic device according to some embodiments.

A display device according to some embodiments may be applied to various electronic devices. The electronic device according to some embodiments may include the display device and may further include a module or a device having another additional function in addition to the display device.

FIG. 1 is a block diagram of an electronic device according to some embodiments of the present disclosure. Referring to FIG. 1, an electronic device ED according to some embodiments may include a display module DM, a processor PR, a memory MR, and a power module EM.

The processor PR may include at least one of a central processing unit (CPU), an application processor (AP), a graphic processing unit (GPU), a communication processor (CP), an image signal processor (ISP), or a controller.

Data information required or utilized for operating the processor PR or the display module DM may be stored in the memory MR. When the processor PR executes an application stored in the memory MR, an image data signal and/or an input control signal may be transmitted to the display module DM, and the display module DM may process the received signal and output image information through a display screen.

The power module EM may include a power supply module such as a power adapter or a battery device and a power conversion module that converts power supplied by the power supply module to generate power required for operating the electronic device ED.

At least one of the components of the electronic device ED may be included in the display device according to some embodiments. Further, some of individual modules functionally included inside one module may be included inside the display device, and the others thereof may be provided separately from the display device. For example, the display device may include the display module DM, and the processor PR, the memory MR, and the power module EM may be provided in the form of other devices in the electronic device ED rather than the display device.

FIG. 2 is a schematic view of the electronic device according to some embodiments.

Referring to FIG. 2, various electronic devices to which the display device according to some embodiments is applied may include an image display electronic device such as a smartphone 10_1a, a tablet PC 10_1b, a laptop computer 10_1c, a television (TV) 10_1d, and a desk monitor 10_1e, a wearable electronic device including a display module such as a smart glasses 10_2a, a head mounted display 10_2b, and a smart watch 10_2c, and a vehicle electronic device 10_3 including a display module such as an instrument panel, a center fascia, a center information display (CID) located on a dashboard, and a room mirror display of a vehicle.

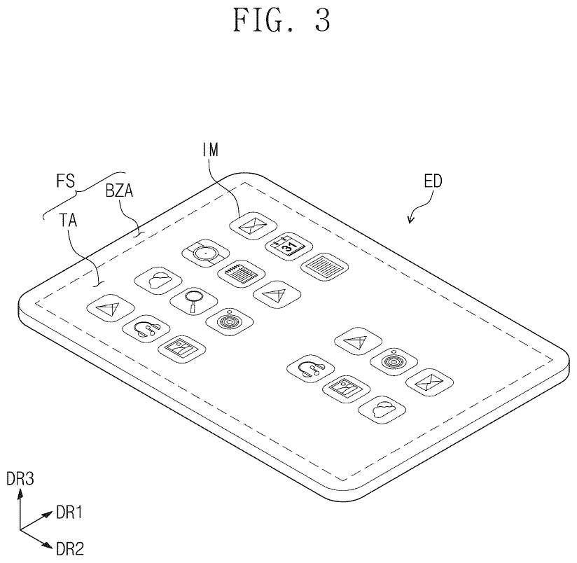

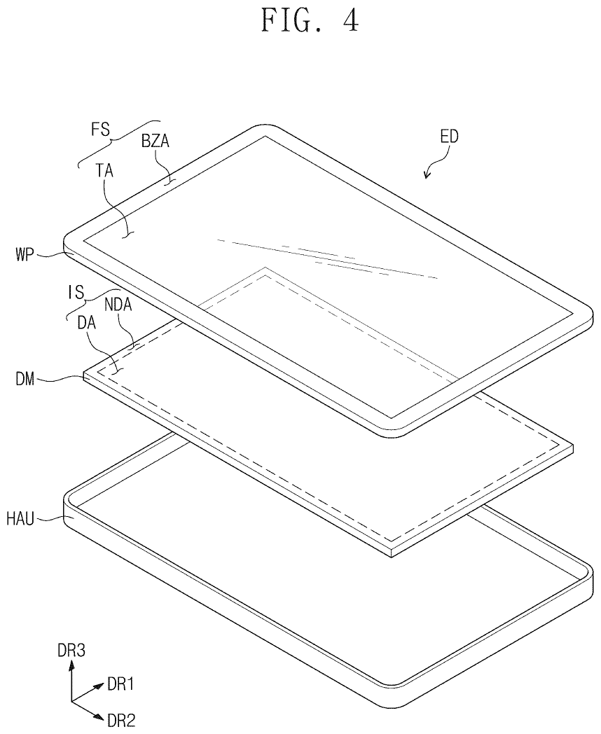

FIG. 3 is a perspective view of the electronic device according to some embodiments of the present disclosure. FIG. 4 is an exploded perspective view of the electronic device according to some embodiments of the present disclosure.

According to some embodiments, the electronic device ED may have a rectangular shape having short sides extending in a first direction DR1 and long sides extending in a second direction DR2 on a plane (or in a plan view, e.g., a direction perpendicular to a display surface of the electronic device ED). However, embodiments of the present disclosure are not limited thereto, and the electronic device ED may have various shapes such as a circular shape and a polygonal shape.

The electronic device ED may display an image IM in a third direction DR3 through a display surface FS parallel to a surface defined by the first direction DR1 and the second direction DR2. The third direction DR3 may be parallel to a normal direction of the display surface FS. The display surface FS on which the image IM is displayed may correspond to a front surface of the electronic device ED. The image IM may include still images (e.g., static images) as well as dynamic images (e.g., video images). FIG. 3 illustrates icon images as an example of the image IM.

According to some embodiments, front surfaces (or upper surfaces) and rear surfaces (or lower surfaces) of members or units may be defined based on a direction in which the image IM is displayed. The front surface and the rear surface may be opposite to each other in the third direction DR3 and a normal direction of the front surface and the rear surface may be parallel to the third direction DR3. A separation distance between the front surface and the rear surface defined in the third direction DR3 may correspond to a thickness of the member (or the unit).

In the specification, the phrases “on a plane” or “in a plan view” may be defined as a state of being viewed along the third direction DR3 toward the electronic device ED. In the specification, the wording “on a cross section” may be defined as a state of being viewed in the first direction DR1 or the second direction DR2. Meanwhile, directions indicated by the first direction DR1, the second direction DR2, and the third direction DR3 are relative concepts and may be changed to other directions.

In the electronic device ED, the display surface FS, on which the image IM is displayed, may correspond to the front surface of the electronic device ED and may correspond to a front surface FS of a window WP (see FIG. 4). Hereinafter, the same reference numeral will be used for the display surface and the front surface of the electronic device ED and the front surface of the window WP. Meanwhile, according to some embodiments, the electronic device ED may include a foldable display device including a folding area and a non-folding area or a bending display device including at least one bending part.

Referring to FIG. 4, the electronic device ED according to some embodiments may include the window WP, the display module DM, and a housing HAU.

The window WP may include an optically transparent insulating material. The window WP may include a transmissive area TA and a bezel area BZA. A user may visually recognize or perceive images provided through the transmissive area TA corresponding to the front surface FS of the window WP.

The transmissive area TA may be an optically transparent area. The bezel area BZA may be an area having a relatively low light transmittance as compared to the transmissive area TA. The bezel area BZA may have a color (e.g., a set or predetermined color). The bezel area BZA may be adjacent to the transmissive area TA and surround (e.g., in a periphery or outside a footprint of) the transmissive area TA in a plan view. The bezel area BZA may define a shape of the transmissive area TA. However, embodiments of the present disclosure are not limited to the illustration, the bezel area BZA may be located adjacent to only one side of the transmissive area TA, and a portion thereof may be omitted.

It is illustrated in FIGS. 3 and 4 that the transmissive area TA has a quadrangular shape. However, this is illustrated by way of example, the transmissive area TA may have various shapes, and the present disclosure is not limited to an embodiment. For example, according to some embodiments, the transmissive area TA may have a generally rectangular or square shape, a circular shape, an irregular shape, a polygonal shape, or an irregular shape, in a plan view.

The display module DM may be located under the window WP. The display module DM may be a component that generates the image IM. The image IM generated by the display module DM is displayed on a display surface IS and is visually recognized or perceived by users from the outside through the transmissive area TA.

The display module DM includes a display area DA and a non-display area NDA. The display area DA may be an area that is activated according to an electric signal. The non-display area NDA may be an area covered by the bezel area BZA. The non-display area NDA is adjacent to the display area DA. The non-display area NDA may surround (e.g., in a periphery or outside a footprint of) the display area DA in a plan view.

The housing HAU may accommodate the display module DM. The housing HAU may provide a base space in which the display module DM is to be located. The housing HAU may be arranged to cover the display module DM so that an upper surface, which is the display surface IS of the electronic device ED, is exposed. The housing HAU may cover a side surface and a bottom surface of the display module DM and may expose the entire upper surface. However, embodiments according to the present disclosure are not limited thereto, and the housing HAU may cover a portion of the upper surface as well as the side surface and the bottom surface of the display module DM.

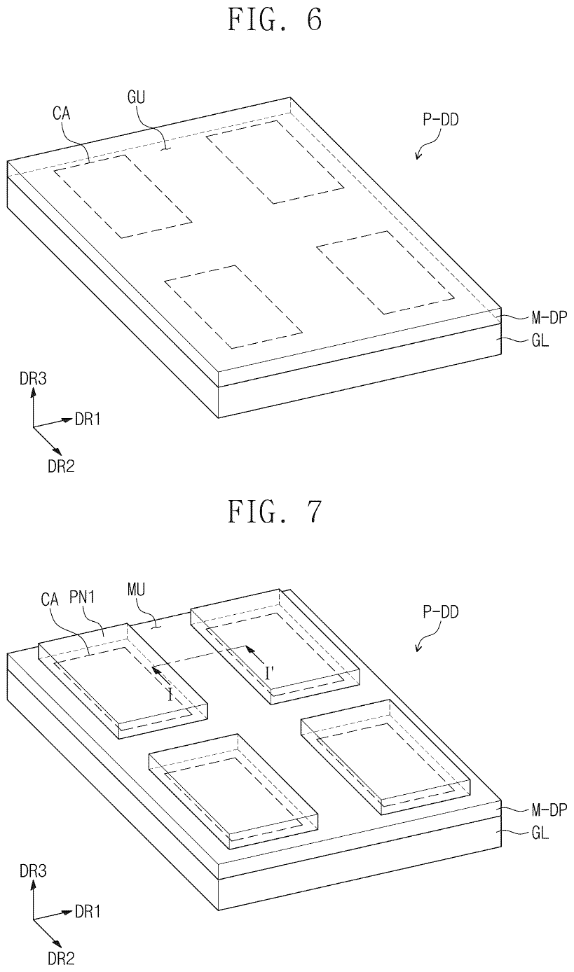

The display device manufactured by the method of manufacturing a display device according to some embodiments of the present disclosure may be manufactured by cutting a preliminary laminated body P-DD (see FIG. 6) including a mother substrate M-DP (see FIG. 6). According to some embodiments of the present disclosure, a plurality of display devices may be manufactured from the one preliminary laminated body P-DD (see FIG. 6). Further, according to some embodiments of the present disclosure, a method of manufacturing a display device having relatively improved reliability of a manufacturing process may be provided. This will be described in more detail below.

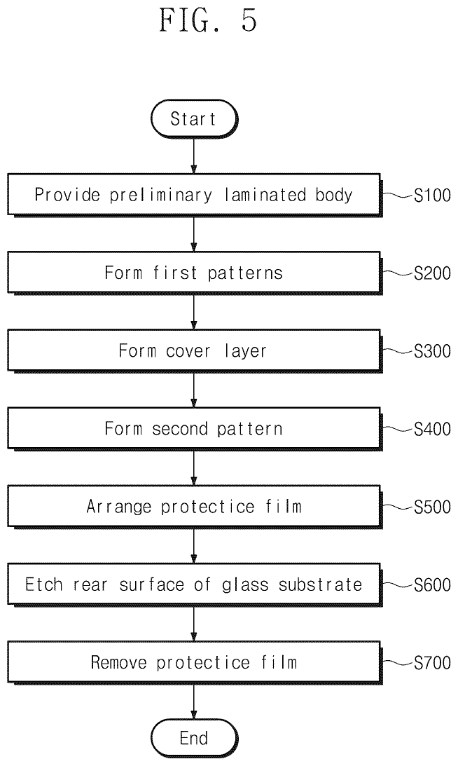

FIG. 5 is a flowchart showing aspects of a method of manufacturing a display device according to some embodiments of the present disclosure. Although FIG. 5 illustrates various operations in a method of manufacturing a display device, embodiments according to the present disclosure are not limited thereto, and according to various embodiments, the method may include additional operations, or fewer operations, or the order of operations may vary, unless otherwise stated or implied, without departing from the spirit and scope of embodiments according to the present disclosure.

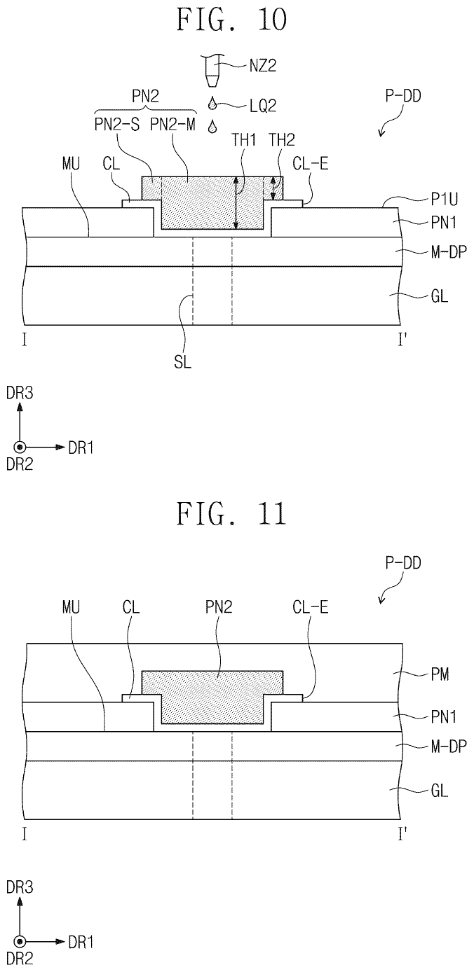

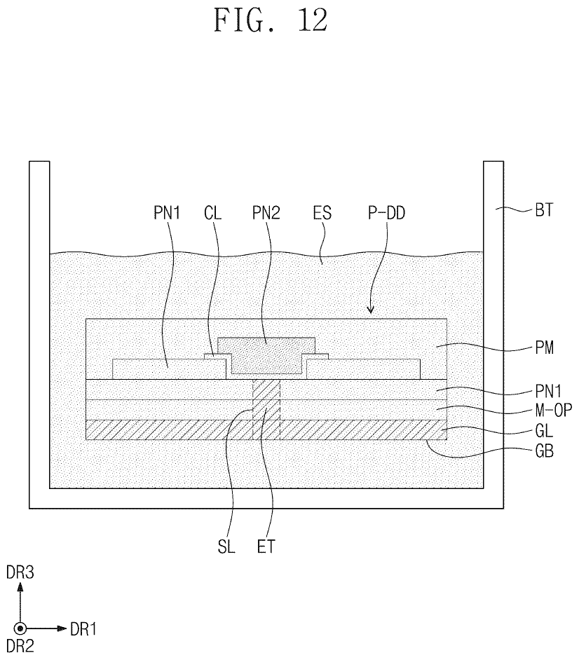

A method of manufacturing a display device according to some embodiments of the present disclosure may include operation S100 of providing the preliminary laminated body P-DD (see FIG. 6) including a glass substrate GL (see FIG. 6) and the mother substrate M-DP (see FIG. 6) which is located on an upper surface GU (see FIG. 6) of the glass substrate GL and in which cell areas CA (see FIG. 6) are defined, operation S200 of forming first patterns PN1 (see FIG. 7) arranged on an upper surface MU (see FIG. 7) of the mother substrate M-DP, overlapping the cell areas CA, and spaced apart from each other, operation S300 of forming a cover layer CL (see FIG. 7) in contact with the upper surface MU of the mother substrate M-DP exposed by the first patterns PN1, operation S400 of forming a second pattern PN2 (see FIG. 10) on the cover layer CL, operation S500 of arranging a protective film PM (see FIG. 11) having acid resistance on the first pattern PN1 and the second pattern PN2, operation S600 of etching a rear surface GB (see FIG. 12) of the glass substrate GL, and operation S700 of removing the protective film PM.

Hereinafter, operations of the method of manufacturing a display device will be described in more detail with reference to the drawings.

FIGS. 6 to 15 are views illustrating operations of the method of manufacturing a display device according to some embodiments of the present disclosure.

FIG. 6 illustrates a state in which operation S100 (see FIG. 5) of providing the preliminary laminated body P-DD is performed. The preliminary laminated body P-DD may include the glass substrate GL and the mother substrate M-DP located on the upper surface GU of the glass substrate GL.

The cell areas CA may be defined in the mother substrate M-DP. Each of the cell areas CA may be an area to be cut to form the display module DM (see FIG. 4). According to some embodiments, the mother substrate M-DP may be cut along an edge of the cell area CA. Accordingly, the plurality of display modules DM (see FIG. 4) may be formed on the one mother substrate M-DP.

Thereafter, referring to FIG. 7, operation S200 (see FIG. 5) of forming the first patterns PN1 on the upper surface MU of the mother substrate M-DP may be performed.

According to some embodiments, operation S200 (see FIG. 5) of forming the first patterns PN1 may be performed by a process of coating the upper surface MU of the mother substrate M-DP with a first liquid solution using a first nozzle. For example, operation S200 (see FIG. 5) of forming the first patterns PN1 may be performed by a process of discharging the first liquid solution onto the upper surface MU of the mother substrate M-DP by an inkjet method. The first liquid solution may include an acryl-based resin.

The first patterns PN1 may overlap the cell areas CA, respectively. In a plan view, an area of each of the first patterns PN1 may be greater than an area of each of the cell areas CA overlapping the first patterns PN1.

The first patterns PN1 may protect the mother substrate M-DP. Further, since the second pattern PN2 (see FIG. 10), which will be described below, is located between the first patterns PN1, the first patterns PN1 may function to define a space in which the second pattern PN2 is to be formed. This will be described in more detail below.

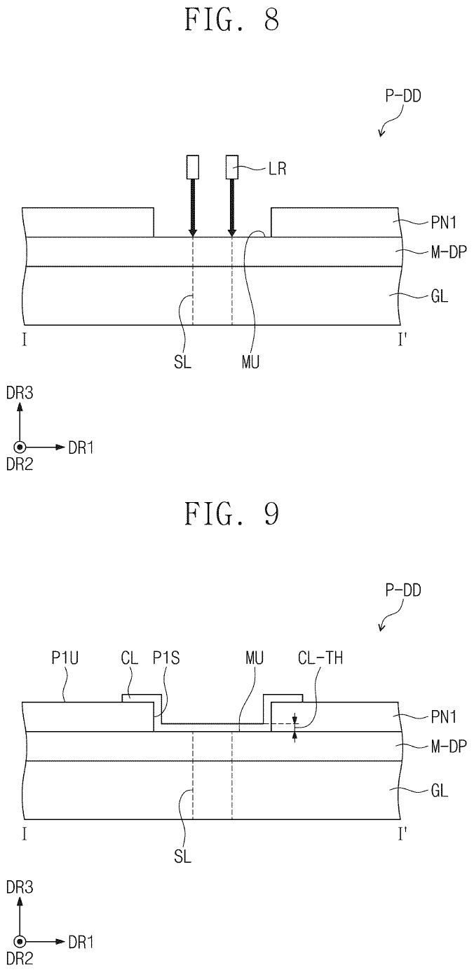

Thereafter, referring to FIG. 8, in the method of manufacturing a display device according to some embodiments, an operation of forming a sketch line SL by etching the mother substrate M-DP exposed by the first patterns PN1 in a direction from the upper surface MU to the glass substrate GL may be further performed.

A laser emitted from a laser device LR may form the sketch line SL on at least portions of the mother substrate M-DP and the glass substrate GL.

On a cross section, the sketch line SL may be parallel in the third direction DR3. The sketch line SL may correspond to a fine gap into which an etching solution ES (see FIG. 12), which will be described below, may be permeated. The preliminary laminated body P-DD may be cut in the third direction DR3 by the etching solution ES (see FIG. 12), which will be described below.

Thereafter, referring to FIG. 9, operation S300 (see FIG. 5) of forming the cover layer CL may be performed.

The cover layer CL may be in contact with the upper surface MU of the mother substrate M-DP exposed by the first patterns PN1. The cover layer CL may be in contact with side surfaces P1S of the first patterns PN1. The cover layer CL may be in contact with upper surfaces P1U of the first patterns PN1.

A thickness CL-TH of the cover layer CL may be in a range of 1 micrometer (μm) to 10 μm.

The cover layer CL may correspond to an inorganic layer. For example, the cover layer CL may include an acryl-based inorganic material.

The cover layer CL may have chemical resistance. For example, the cover layer CL may have acid resistance. Accordingly, the etching solution ES (see FIG. 12), which will be described below, permeating into the upper surface MU of the mother substrate M-DP may be prevented or reduced.

The cover layer CL may prevent or reduce the second pattern PN2 (see FIG. 10), which will be described in more detail below, and the first pattern PN1 being in direct contact with each other. Accordingly, the cover layer CL may prevent or reduce a residue being formed on the first pattern PN1 when the second pattern PN2 is peeled off. That is, it may be possible to prevent or reduce defects occurring in a process of manufacturing a display device because a surface of the first pattern PN1 is non-flat due to the residue. Further, it may be possible to prevent or reduce defects occurring in the process of manufacturing a display device because foreign substances or contaminants remain on the surface of the first pattern PN1. Functions and effects of the cover layer CL will be described in more detail below.

Hereinafter, referring to FIG. 10, operation S400 (see FIG. 5) of forming the second pattern PN2 on the cover layer CL may be performed.

Operation S400 (see FIG. 5) of forming the second pattern PN2 may be performed by a process of discharging a second liquid solution LQ2 onto the upper surface MU of the mother substrate M-DP. For example, operation S400 of forming the second pattern PN2 may be performed by a process of discharging the second liquid solution LQ2 by an inkjet method. The second liquid solution LQ2 discharged from a second nozzle NZ2 may be laminated on the cover layer CL.

The second pattern PN2 may include a central portion PN2-M and side portions PN2-S. The central portion PN2-M may have a first thickness TH1, and the side portions PN2-S may have a second thickness TH2. The first thickness TH1 may be greater than the second thickness TH2.

In a plan view, an area in which the cover layer CL overlaps the upper surface P1U of the first pattern PN1 may be greater than an area in which the second pattern PN2 overlaps the upper surface P1U of the first pattern PN1. Accordingly, an end CL-E of the cover layer CL may be exposed from the second pattern PN2.

The second pattern PN2 may be spaced apart from the first pattern PN1 with the cover layer CL interposed therebetween. That is, the cover layer CL may function to prevent or reduce contact between the first pattern PN1 and the second pattern PN2. The first pattern PN1 and the second pattern PN2 may not be in contact with each other.

Thereafter, referring to FIG. 11, operation S500 (see FIG. 5) of arranging the protective film PM on the first pattern PN1 and the second pattern PN2 may be performed.

The protective film PM may cover the second pattern PN2, the first pattern PN1, and the cover layer CL. The protective film PM may cover the end CL-E of the cover layer CL.

The protective film PM may have chemical resistance. For example, the protective film PM may have acid resistance. Accordingly, in operation S600 (see FIG. 5) of etching the rear surface GB of the glass substrate GL, which will be described below, the protective film PM may effectively prevent or reduce the etching solution ES (see FIG. 12) permeating in a direction of the upper surface MU of the mother substrate M-DP.

Thereafter, referring to FIG. 12, operation S600 (see FIG. 5) of etching the rear surface GB of the glass substrate GL may be performed. Operation S600 of etching the rear surface GB of the glass substrate GL includes an operation of dipping the preliminary laminated body P-DD into the etching solution ES.

FIG. 12 illustrates, by way of example, that the preliminary laminated body P-DD is dipped into the etching solution ES filled in a bath BT.

The etching solution ES may have a property of etching a glass material. For example, the etching solution ES may include hydrofluoric acid (HF). However, a material constituting the etching solution ES is not particularly limited as long as the material has a property of etching a glass material.

For convenience of description, an etching area ET to be etched in the preliminary laminated body P-DD is displayed through hatching. The rear surface GB of the glass substrate GL included in the preliminary laminated body P-DD may be in contact with the etching solution ES. Accordingly, the etching solution ES may etch the rear surface GB of the glass substrate. Thus, a thickness of the glass substrate GL may be reduced. Further, at least a portion of the etching solution ES may be permeated along the sketch line SL. Accordingly, at least a portion of the mother substrate M-DP may be removed.

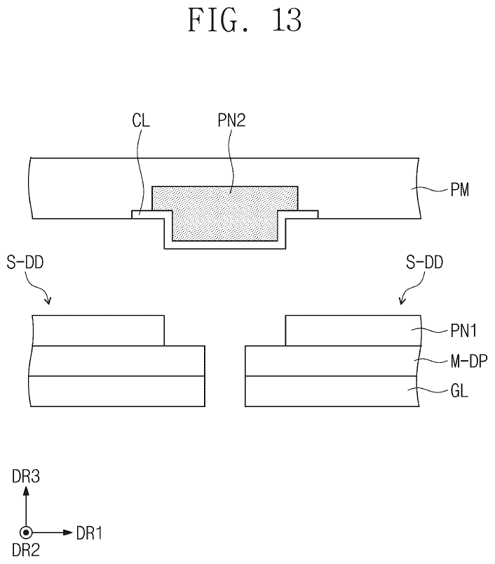

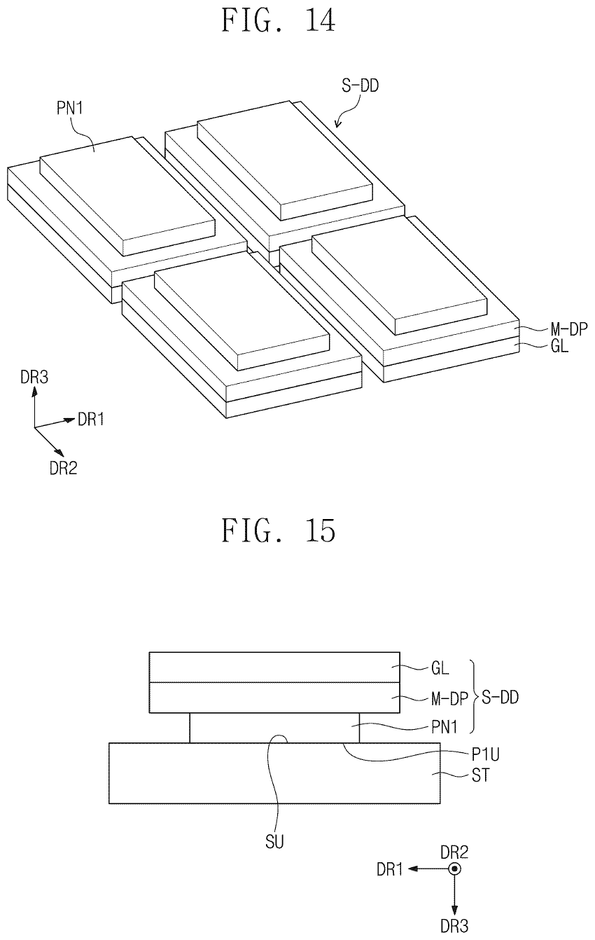

Thereafter, referring to FIGS. 13 and 14, operation S700 (see FIG. 5) of removing the protective film PM may be performed. When the protective film PM is removed, the second pattern PN2 attached to a rear surface of the protective film PM and the cover layer CL attached to a rear surface of the second pattern PN2 may be removed together.

In this case, the method of manufacturing a display device according to some embodiments of the present disclosure may be characterized in that “adhesive interface characteristics” are differentiated. For example, an adhesive force between the first pattern PN1 and the cover layer CL may be smaller than an adhesive force between the first pattern PN1 and the second pattern PN2. That is, the cover layer CL may prevent or reduce the first pattern PN1 and the second pattern PN2 adhering to each other. Accordingly, it may be possible to effectively prevent or reduce the residue of the second pattern PN2 remaining on the first pattern PN1 and to prevent or reduce reliability of the method of manufacturing a display device being reduced in a subsequent process.

Accordingly, a plurality of sub-laminated bodies S-DD may be formed. Each of the sub-laminated bodies S-DD may include the glass substrate GL, the mother substrate M-DP, and the first pattern PN1. FIG. 14 illustrates, by way of example, that four sub-laminated bodies S-DD are formed. However, the number of sub-laminated bodies S-DD formed from the one preliminary laminated body P-DD (see FIG. 11) is not limited to the illustration.

Thereafter, referring to FIG. 15, the method of manufacturing a display device according to some embodiments may further include an operation of arranging the sub-laminated body S-DD on a stage ST after operation S700 (see FIG. 5) of removing the protective film PM. In this case, unlike those described with reference to FIGS. 6 to 14, the preliminary laminated body P-DD may be inverted vertically. However, in FIG. 15, an “upper surface” and a “rear surface” of each component will be expressed consistently with those described with reference to FIGS. 6 to 14.

In this case, the first pattern PN1 may be in contact with the stage ST. The upper surface P1U of the first pattern PN1 may be in contact with an upper surface SU of the stage ST.

The method of manufacturing a display device according to some embodiments of the present disclosure includes operation S300 (see FIG. 5) of forming the cover layer CL (see FIG. 9) such that the first pattern PN1 and the second pattern PN2 are not in contact with each other. Thus, in a process of removing the second pattern PN2 (see FIG. 13), it is possible to prevent or reduce the residue of the second pattern PN2 remaining on the upper surface P1U of the first pattern PN1 or to prevent or reduce the upper surface P1U of the first pattern PN1 being deformed by the residue. Accordingly, the upper surface P1U of the first pattern PN1 may be provided as a flat and even surface. Accordingly, the sub-laminated body S-DD may be stably arranged on the stage ST, and reliability in a subsequent process may be relatively improved.

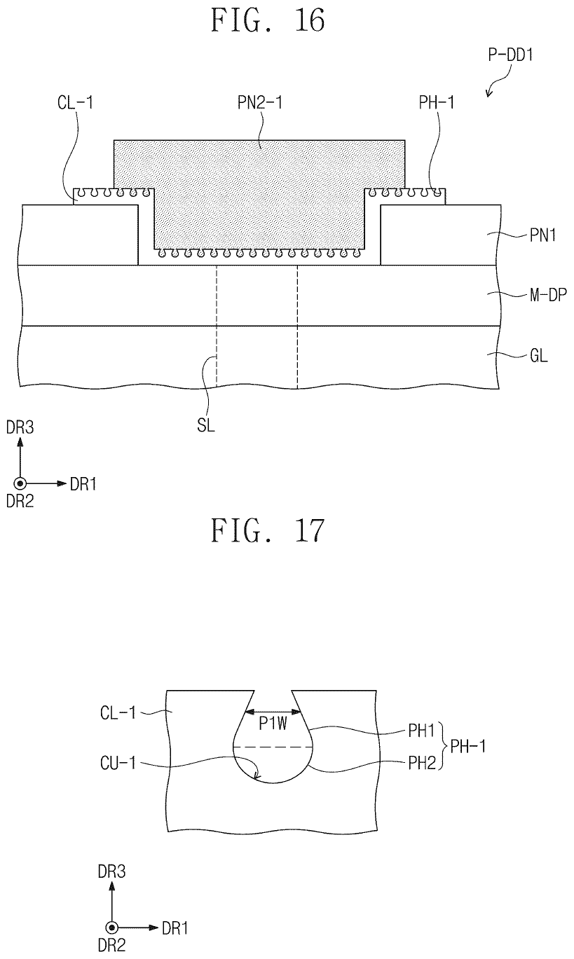

FIGS. 16 and 17 are views illustrating operations of the method of manufacturing a display device according to some embodiments of the present disclosure.

The components identical/similar to those described with reference to FIGS. 1 to 15 are designated by the identical/similar reference numerals, some duplicated description thereof may be omitted, and differences therebetween will be mainly described.

The method of manufacturing a display device according to some embodiments may further include an operation step of forming recessed patterns PH-1 by etching an upper surface CU-1 of a cover layer CL-1 after operation S300 (see FIG. 5) of forming the cover layer CL. According to some embodiments, the operation of forming the recessed patterns PH-1 may be performed by a process of etching a portion of the upper surface CU-1 of the cover layer CL-1 through a lithography process or etching the portion of the upper surface CU-1 of the cover layer CL-1 through a laser.

FIG. 16 may correspond to operation S400 (see FIG. 5) of forming the second pattern PN2 described with reference to FIG. 10. FIG. 17 may be an enlarged view of the one recessed pattern PH-1 in FIG. 16.

Referring to FIGS. 16 and 17, a preliminary laminated body P-DD1 according to some embodiments may include the glass substrate GL, the mother substrate M-DP, the first pattern PN1, the cover layer CL-1, and a second pattern PN2-1.

Each of the recessed patterns PH-1 may include a first portion PH1 and a second portion PH2. In this case, a width P1W of the first portion PH1 may be increased in a direction closer to the glass substrate GL, and a width P1W of the second portion PH2 may be decreased in a direction closer to the glass substrate GL. That is, the width P1W of the first portion PH1 may be increased in an opposite direction to the third direction DR3, and the width P1W of the second portion PH2 may be decreased in an opposite direction to the third direction DR3.

The upper surface CU-1 of the cover layer CL-1 defining each of the recessed patterns PH-1 may include a curved surface. On a cross section, each of the recessed patterns PH-1 may be expressed as a “jar shape” or a “water drop shape” in which a boundary portion between the first portion PH1 and the second portion PH2 is convex.

According to some embodiments, the second pattern PN2-1 may be filled in the recessed patterns PH-1. Accordingly, a coupling force between the second pattern PN2-1 and the cover layer CL-1 may be increased. FIG. 16 illustrates, by way of example, that only some of the recessed patterns PH-1 is filled, but a ratio in which the recessed patterns PH-1 are filled by the second pattern PN2-1 is not limited to the illustration.

Thus, when operation S700 (see FIG. 5) of removing the protective film PM is performed, the second pattern PN2-1 and the cover layer CL-1 may be easily peeled off from the first pattern PN1.

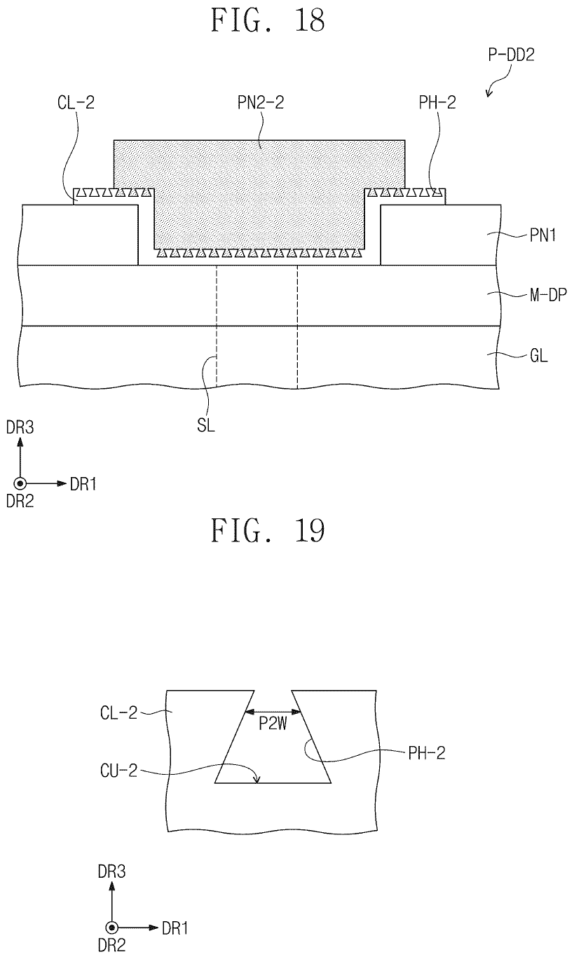

FIGS. 18 and 19 are views illustrating operations of the method of manufacturing a display device according to some embodiments of the present disclosure.

The components identical/similar to those described with reference to FIGS. 1 to 15 are designated by the identical/similar reference numerals, some duplicated description thereof may be omitted, and differences therebetween will be mainly described.

The method of manufacturing a display device according to some embodiments may further include an operation of forming recessed patterns PH-2 by etching an upper surface CU-2 of a cover layer CL-2 after operation S300 of forming the cover layer CL-2. According to some embodiments, the operation of forming the recessed patterns PH-2 may be performed by a process of patterning the upper surface CU-2 of the cover layer CL-2 through a lithography process or patterning the upper surface CU-2 of the cover layer CL-2 through a laser.

FIG. 18 may correspond to an operation of forming the second pattern PN2 described with reference to FIG. 10. FIG. 19 may be an enlarged view of the one recessed pattern PH-2 in FIG. 18.

Referring to FIGS. 18 and 19 together, a preliminary laminated body P-DD2 according to some embodiments may include the glass substrate GL, the mother substrate M-DP, the first pattern PN1, the cover layer CL-2, and a second pattern PN2-2.

On a cross section, each of the recessed patterns PH-2 may have an “inverted tapered shape.” For example, a width P2W of each of the recessed patterns PH-2 may be increased in the opposite direction to the third direction DR3.

According to some embodiments, the second pattern PN2-2 may be filled in the recessed patterns PH-2. Accordingly, a coupling force between the second pattern PN2-2 and the cover layer CL-2 may be increased. FIG. 18 illustrates, by way of example, that only some of the recessed patterns PH-2 is filled, but a ratio in which the recessed patterns PH-2 are filled by the second pattern PN2-2 is not limited to the illustration.

Thus, when operation S700 (see FIG. 5) of removing the protective film PM is performed, the second pattern PN2-2 and the cover layer CL-2 may be easily peeled off from the first pattern PN1.

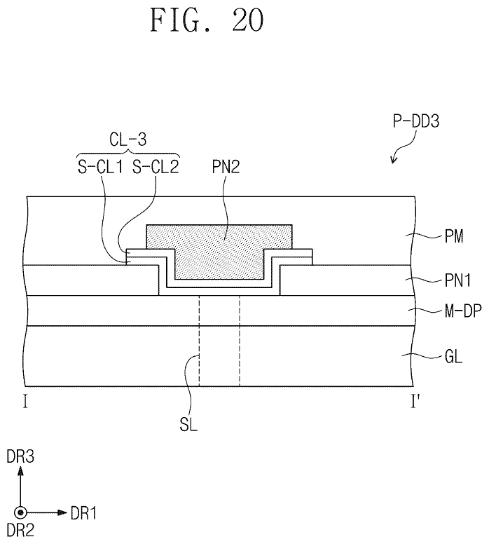

FIG. 20 is a view illustrating operations of the method of manufacturing a display device according to some embodiments of the present disclosure.

The components identical/similar to those described with reference to FIGS. 1 to 15 are designated by the identical/similar reference numerals, some duplicated description thereof may be omitted, and differences therebetween will be mainly described.

According to some embodiments, operation S300 (see FIG. 5) of forming a cover layer CL-3 may include an operation of forming a first sub-cover layer S-CL1 and an operation of forming a second sub-cover layer S-CL2 on the first sub-cover layer S-CL1.

Each of the first sub-cover layer S-CL1 and the second sub-cover layer S-CL2 may include an inorganic material. However, constituent materials of the first sub-cover layer S-CL1 and the second sub-cover layer S-CL2 may be different from each other. Accordingly, the first sub-cover layer S-CL1 and the second sub-cover layer S-CL2 may have different adhesive forces with respect to the same object.

An adhesive force between the first sub-cover layer S-CL1 and the first pattern PN1 may be smaller than an adhesive force between the second sub-cover layer S-CL2 and the first pattern PN1. An adhesive force between the second sub-cover layer S-CL2 and the first sub-cover layer S-CL1 may be greater than an adhesive force between the first sub-cover layer S-CL1 and the first pattern PN1.

That is, the first sub-cover layer S-CL1 and the second sub-cover layer S-CL2 may relatively strongly adhere to each other, but the first sub-cover layer S-CL1 may relatively weakly adhere to the first pattern PN1. Accordingly, when the protective film PM is removed, the cover layer CL-3 may be easily peeled off, but the residue of the cover layer CL-3 remaining on the first pattern PN1 may be prevented or reduced.

According to some embodiments of the present disclosure, a method of manufacturing a display device having relatively improved process reliability may be provided.

For example, a method of manufacturing a display device, which includes a process of etching a glass substrate and removing a protective film and has relatively improved process reliability, may be provided.

Although aspects of some embodiments of the present disclosure have been described above with reference to aspects of some embodiments of the present disclosure, it may be understood that those skilled in the art or those having ordinary knowledge in the art may variously modify and change the present disclosure without departing from the spirit and technical scope of embodiments according to the present disclosure described in the appended claims, and their equivalents. Accordingly, the technical scope of the present disclosure is not limited to the detailed description of the specification, but should be defined by the appended claims, and their equivalents.

What is claimed is:

1. A method of manufacturing a display device, the method comprising:
providing a preliminary laminated body including a glass substrate and a mother substrate on an upper surface of the glass substrate and in which cell areas are defined;
forming first patterns on an upper surface of the mother substrate, overlapping the cell areas, and spaced apart from each other;
forming a cover layer in contact with the upper surface of the mother substrate exposed by the first patterns;
forming a second pattern on the cover layer;
arranging a protective film having acid resistance on the first pattern and the second pattern;
etching a rear surface of the glass substrate; and
removing the protective film.

2. The method of claim 1, wherein the cover layer contacts side surfaces of the first patterns and upper surfaces of the first patterns.

3. The method of claim 1, wherein an end of the cover layer is exposed from the second pattern and contacts the protective film.

4. The method of claim 1, wherein, in a plan view, an area in which the cover layer overlaps upper surfaces of the first patterns is larger than an area in which the second pattern overlaps the upper surfaces of the first patterns.

5. The method of claim 1, wherein the forming of the first patterns includes discharging a first liquid solution onto the upper surface of the mother substrate in an inkjet method, and
wherein the first liquid solution contains an acryl-based resin.

6. The method of claim 1, wherein the forming of the second pattern includes discharging a second liquid solution onto the upper surface of the mother substrate in an inkjet method.

7. The method of claim 1, wherein the cover layer has acid resistance.

8. The method of claim 1, wherein the cover layer contains an acryl-based inorganic material.

9. The method of claim 1, wherein a thickness of the cover layer is in a range of 1 micrometers (μm) to 10 μm.

10. The method of claim 1, wherein the second pattern includes a central portion having a first thickness and a side portion having a second thickness smaller than the first thickness.

11. The method of claim 1, further comprising, after the forming of the first patterns:
forming a sketch line by etching the mother substrate exposed by the first patterns in a direction from the upper surface of the mother substrate to the glass substrate.

12. The method of claim 1, wherein the etching of the rear surface of the glass substrate includes dipping the preliminary laminated body into an etching solution.

13. The method of claim 1, wherein, in the removing of the protective film, the second pattern and the cover layer attached to a rear surface of the protective film are removed together with the protective film.

14. The method of claim 1, further comprising, after the forming of the cover layer:
forming recessed patterns by etching an upper surface of the cover layer,
wherein the second pattern is filled in at least some of the recessed patterns, and
wherein, on a cross section, each of the recessed patterns has a first portion of which a width is increased in a direction closer to the glass substrate and a second portion of which a width is decreased in the direction closer to the glass substrate.

15. The method of claim 14, wherein the upper surface of the cover layer, which defines each of the recessed patterns, includes a curved surface.

16. The method of claim 14, wherein, on the cross section, each of the recessed patterns has an inverted tapered shape.

17. The method of claim 1, wherein a sub-laminated body is formed from the preliminary laminated body by the removing of the protective film,
wherein the method further comprises arranging the sub-laminated body on a stage, and
wherein, in the arranging of the sub-laminated body on the stage, the first patterns contact the stage.

18. The method of claim 1, wherein the forming of the cover layer includes forming a first sub-cover layer and forming a second sub-cover layer on the first sub-cover layer, and
wherein an adhesive force between the second sub-cover layer and the first sub-cover layer is greater than an adhesive force between the first sub-cover layer and the first patterns.

19. A method of manufacturing an electronic device configured to provide an image and including a display device and a power module, the method comprising:
providing a preliminary laminated body including a glass substrate and a mother substrate on an upper surface of the glass substrate and in which cell areas are defined;
forming first patterns overlapping the cell areas on an upper surface of the mother substrate and spaced apart from each other;
forming a cover layer contacting the upper surface of the mother substrate exposed by the first patterns;
forming a second pattern on the cover layer;
arranging a protective film on the first pattern and the second pattern;
etching a rear surface of the glass substrate; and
removing the protective film.

20. An electronic device including a display device and a power module and configured to provide an image, the electronic device being manufactured by a method of manufacturing a electronic device, the method including:
providing a preliminary laminated body including a glass substrate and a mother substrate on an upper surface of the glass substrate and in which cell areas are defined;
forming first patterns overlapping the cell areas on an upper surface of the mother substrate and spaced apart from each other;
forming a cover layer contacting the upper surface of the mother substrate exposed by the first patterns;
forming a second pattern on the cover layer;
arranging a protective film on the first pattern and the second pattern;
etching a rear surface of the glass substrate; and
removing the protective film.
